(19) United States
(12) Patent Application Publication
(10) Pub. No.: US 2008/0121918 A1
(43) Pub. Date: May 29, 2008

(54) HIGH LIGHT EXTRACTION EFFICIENCY SPHERE LED

(75) Inventors: Steven P. DenBaars, Goleta, CA (US); Shuji Nakamura, Santa Barbara, CA (US); Hisashi Masui, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/940,872

(22) Filed: Nov. 15, 2007

Related U.S. Application Data
(60) Provisional application No. 60/866,025, filed on Nov. 15, 2006.

(51) Int. Cl. H01L 33/00

(52) U.S. Cl. 257/98; 257/E33.061; 257/E33.058

(57) ABSTRACT

This invention is related to LED Light Extraction for optoelectronic applications. More particularly the invention relates to (Al, Ga, In)N combined with optimized optics for highly efficient (Al, Ga, In)N based light emitting diodes applications, and its fabrication method. A further extension is the general combination of a shaped high refractive index light extraction material combined with a sphere shaped molding.

### CROSS-REFERENCE TO RELATED APPLICATIONS

This application is related to the following co-pending and commonly-assigned applications:

U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Serial No. US2003/03921, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 11/054,271, filed on Feb. 9, 2005, by Rajat Sharma, P. Morgan Pattison, John F. Kaeding, and Shuji Nakamura, entitled “SEMICONDUCTOR LIGHT EMITTING DEVICE,” attorney's docket number 30794.112-US-01 (2004-208);

U.S. Utility application Ser. No. 11/175,761, filed on Jul. 6, 2005, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-U1 (2004-455), which application claims the benefit under 35 U.S.C Section 119(e) of U.S. Provisional Application Ser. No. 60/585,673, filed Jul. 6, 2004, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-P1 (2004-455-1);

U.S. Utility application Ser. No. 11/067,957, filed Feb. 28, 2005, by Claude C. A. Weisbuch, Aurelien J. F. David, James S. Speck and Steven P. DenBaars, entitled “HORIZONTAL EMITTING, VERITCAL EMITTING, BEAM SHAPED, DISTRIBUTED FEEDBACK (DFB) LASERS BY GROWTH OVER A PATTERNED SUBSTRATE,” attorneys' docket number 30794.121-US-01 (2005-144-1);

U.S. Utility application Ser. No. 11/923,414, filed Oct. 24, 2007, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-C1 (2005-145-2), which application is a continuation of U.S. Pat. No. 7,291,864, issued Nov. 6, 2007, to Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-1);

U.S. Utility application Ser. No. 11/067,956, filed Feb. 28, 2005, by Aurelien J. F. David, Claude C. A Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1); U.S. Utility application Ser. No. 11/403,624, filed Apr. 13, 2006, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-U1 (2005-482-2), which application claims the benefit under 35 U.S.C Section 119(e) of U.S. Provisional Application Ser. No. 60/670,810, filed Apr. 13, 2005, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-P1 (2005-482-1);

U.S. Utility application Ser. No. 11/403,288, filed Apr. 13, 2006, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-U1 (2005-509-2), which application claims the benefit under 35 U.S.C Section 119(e) of U.S. Provisional Application Ser. No. 60/670,790, filed Apr. 13, 2005, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-P1 (2005-509-1);

U.S. Utility application Ser. No. 11/454,691, filed on Jun. 16, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDING STRUCTURE FOR OPTOELECTRONIC APPLICATIONS AND ITS FABRICATION METHOD,” attorneys' docket number 30794.134-US-U1 (2005-536-4), which application claims the benefit under 35 U.S.C Section 119(e) of U.S. Provisional Application Ser. No. 60/691,710, filed on Jun. 17, 2005, by Akihiko Murai, Christina Ye Chen, Lee S. McCarthy, Steven P. DenBaars, Shuji Nakamura, and Umesh K. Mishra, entitled “(Al, Ga, In)N AND ZnO DIRECT WAFER BONDING STRUCTURE FOR OPTOELECTRONIC APPLICATIONS, AND ITS FABRICATION METHOD,” attorneys' docket number 30794.134-US-P1 (2005-536-1), U.S. Provisional Application Ser. No. 60/732,319, filed on Nov. 1, 2005, by Akihiko Murai, Christina Ye Chen, Daniel B. Thompson, Lee S. McCarthy, Steven P. DenBaars, Shuji Nakamura, and Umesh K. Mishra, entitled “(Al, Ga, In)N AND ZnO DIRECT WAFER BONDED STRUCTURE FOR OPTOELECTRONIC APPLICATIONS, AND ITS FABRICATION METHOD,” attorneys' docket number 30794.134-US-P2 (2005-536-2), and U.S. Provisional Application Ser. No. 60/764,881, filed on Feb. 3, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDED STRUCTURE FOR OPTOELECTRONIC APPLICATIONS AND ITS FABRICATION METHOD,” attorneys' docket number 30794.134-US-P3 (2005-536-3);

U.S. Utility application Ser. No. 11/251,365 filed Oct. 14, 2005, by Frederic S. Diana, Aurelien J. F. David, Pierre M. Petroff, and Claude C. A. Weisbuch, entitled “PHOTONIC STRUCTURES FOR EFFICIENT LIGHT EXTRACTION AND CONVERSION IN MULTI-COLOR LIGHT EMITTING DEVICES,” attorneys' docket number 30794.142-US-01 (2005-534-1);

U.S. Utility application Ser. No. 11/633,148, filed Dec. 4, 2006, Claude C. A. Weisbuch and Shuji Nakamura, entitled “IMPROVED HORIZONTAL EMITTING, VERTICAL EMITTING, BEAM SHAPED, DISTRIBUTED FEEDBACK (DFB) LASERS FABRICATED BY GROWTH OVER A PATTERNED SUBSTRATE WITH MULTIPLE OVERGROWTH,” attorneys' docket number 30794.143-US-U1 (2005-721-2), which application claims the benefit under 35 U.S.C Section 119(e) of U.S. Provisional Application Ser. No. 60/741,935, filed Dec. 2, 2005, Claude C. A. Weisbuch and Shuji Nakamura, entitled “IMPROVED HORIZONTAL EMITTING, VERTICAL EMITTING, BEAM SHAPED, DFB LASERS FABRICATED BY GROWTH OVER PATTERNED SUBSTRATE WITH MULTIPLE OVERGROWTH,” attorneys' docket number 30794.143-US-P1 (2005-721-1);

U.S. Utility application Ser. No. 11/593,268, filed on Nov. 6, 2006, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-U1 (2006-271-2), which application claims the benefit under 35 U.S.C Section 119(e) of U.S. Provisional Application Ser. No. 60/734,040, filed on Nov. 4, 2005, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-P1 (2006-271-1);

U.S. Utility application Ser. No. 11/608,439, filed on Dec. 8, 2006, by Steven P. DenBaars, Shuji Nakamura and James S. Speck, entitled “HIGH EFFICIENCY LIGHT EMITTING DIODE (LED),” attorneys' docket number 30794.164-US-U1 (2006-318-3), which application claims the benefit under 35 U.S.C Section 119(e) of U.S. Provisional Application Ser. No. 60/748,480, filed on Dec. 8, 2005, by Steven P. DenBaars, Shuji Nakamura and James S. Speck, entitled “HIGH EFFICIENCY LIGHT EMITTING DIODE (LED),” attorneys' docket number 30794.164-US-P1 (2006-318-1), and U.S. Provisional Application Ser. No. 60/764,975, filed on Feb. 3, 2006, by Steven P. DenBaars, Shuji Nakamura and James S. Speck, entitled “HIGH EFFICIENCY LIGHT EMITTING DIODE (LED),” attorneys' docket number 30794.164-US-P2 (2006-318-2);

U.S. Utility application Ser. No. 11/676,999, filed on Feb. 20, 2007, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-U1 (2006-422-2), which application claims the benefit under 35 U.S.C Section 119(e) of U.S. Provisional Application Ser. No. 60/774,467, filed on Feb. 17, 2006, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-P1 (2006-422-1); U.S. Utility patent application Ser. No. ______, filed on Nov. 15, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794. 191-US-U1 (2007-047-3), which application claims the benefit under 35 U.S.C Section 119(e) of U.S. Provisional Patent Application Ser. No. 60/866,014, filed on Nov. 15, 2006, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794. 191-US-P1 (2007-047-1), and U.S. Provisional Patent Application Ser. No. 60/883,977, filed on Jan. 8, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794. 191-US-P2 (2007-047-2);

U.S. utility patent application Ser. No. ______, filed on Nov. 15, 2007, by Claude C. A. Weisbuch, James S. Speck and Steven P. DenBaars entitled “HIGH EFFICIENCY WHITE, SINGLE OR MULTI-COLOUR LED BY INDEX MATCHING STRUCTURES,” attorney's docket number 30794. 196-US-U1 (2007-114-2), which application claims the benefit under 35 U.S.C Section 119(e) of U.S. Provisional Patent Application Ser. No. 60/866,026, filed on Nov. 15, 2006, by Claude C. A. Weisbuch, James S. Speck and Steven P. DenBaars entitled “HIGH EFFICIENCY WHITE, SINGLE OR MULTI-COLOUR LED BY INDEX MATCHING STRUCTURES,” attorney's docket number 30794. 196-US-P1 (2007-114-1);

U.S. Utility patent application Ser. No. ______, filed on same date herewith, by Aurelien J. F. David, Claude C. A. Weisbuch, Steven P. DenBaars and Stacia Keller, entitled “HIGH LIGHT EXTRACTION EFFICIENCY LIGHT EMITTING DIODE (LED) WITH EMITTERS WITHIN STRUCTURED MATERIALS,” attorney's docket number 30794.197-US-U1 (2007-113-2), which application claims the benefit under 35 U.S.C Section 119(e) of U.S. Provisional patent application Ser. No. ______, filed on same date herewith, by Aurelien J. F. David, Claude C. A. Weisbuch, Steven P. DenBaars and Stacia Keller, entitled “HIGH LIGHT EXTRACTION EFFICIENCY LED WITH EMITTERS WITHIN STRUCTURED MATERIALS,” attorney's docket number 30794.197-US-P1 (2007-113-1);

U.S. Utility patent application Ser. No. ______, filed on Nov. 15, 2007, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-U1 (2007-161-2), which application claims the benefit under 35 U.S.C Section 119(e) of U.S. Provisional Patent Application Ser. No. 60/866,027, filed on Nov. 15, 2006, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-P1 (2007-161-1);

U.S. Utility patent application Ser. No. ______, filed on Nov. 15, 2007, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-U1 (2007-270-2), which application claims the benefit under 35 U.S.C Section 119(e) of U.S. Provisional Patent Application Ser. No. 60/866,024, filed on Nov. 15, 2006, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-P1 (2007-270-1);

U.S. Utility patent application Ser. No. ______, filed on Nov. 15, 2007, by Shuji Nakamura and Steven P. DenBaars, entitled “STANDING TRANSPARENT MIRROR-LESS (STML) LIGHT EMITTING DIODE,” attorney's docket number 30794.205-US-U1 (2007-272-2), which application claims the benefit under 35 U.S.C Section 119(e) of U.S. Provisional Patent Application Ser. No. 60/866,017, filed on Nov. 15, 2006, by Shuji Nakamura and Steven P. DenBaars, entitled “STANDING TRANSPARENT MIRROR-LESS (STML) LIGHT EMITTING DIODE,” attorney's docket number 30794.205-US-P1 (2007-272-1); and

U.S. Utility patent application Ser. No. ______, filed on Nov. 15, 2007, by Steven P. DenBaars, Shuji Nakamura and James S. Speck, entitled “TRANSPARENT MIRROR-LESS (TML) LIGHT EMITTING DIODE,” attorney's docket number 30794.206-US-U1 (2007-273-2), which application claims the benefit under 35 U.S.C Section 119(e) of U.S. Provisional Patent Application Ser. No. 60/866,023, filed on Nov. 15, 2006, by Steven P. DenBaars, Shuji Nakamura and James S. Speck, entitled “TRANSPARENT MIRROR-LESS (TML) LIGHT EMITTING DIODE,” attorney's docket number 30794.206-US-P1 (2007-273-1); all of which applications are incorporated by reference herein.

This application claims the benefit under 35 U.S.C. Section 119(e) of co-pending and commonly-assigned U.S. provisional patent application Ser. No. 60/866,025, filed Nov. 15, 2006, entitled “HIGH LIGHT EXTRACTION EFFICIENCY SPHERE LED,” by Steven P. DenBaars et al., which application is incorporated by reference herein.

### BACKGROUND OF THE INVENTION

1. Field of the Invention

This invention is related to LED Light Extraction and white LEDs with high luminous efficacy for optoelectronic applications. More particularly the invention relates to (Al, Ga, In)N LEDs and light extraction structure combined with a spherical package to extract light emitted in all directions. The overall effect is to achieve a device with superior luminous efficacy and a high output power.

2. Description of the Related Art

(Note: This application references a number of different publications as indicated throughout the specification. A list of these different publications can be found below in the section entitled “References.” Each of these publications is incorporated by reference herein.)

In conventional Light Emitting Diodes (LEDs), in order to increase the light output power for the front side of the LED, the emitting light is reflected by a mirror on the backside of the sapphire substrate, or a mirror coating is placed on the lead frame when the bonding material is transparent at the emission wavelength. This reflected light is often re-absorbed by the emitting layer (active layer) because the photon energy is almost same as the band-gap energy of the quantum well of a AlInGaN multi-quantum well (MQW). Thus, the efficiency or output power of the LEDs is decreased due to the re-absorption of LED light by the emitting layer. See FIGS. 2-3. From the top side of p-type layer, the semi-transparent thin metal or ITO or ZnO transparent electrode was used to improve the light extraction efficiency. (J. J. Appl. Phys. 34, L797-99 (1995)), (J. J. Appl. Phys. 43, L180-82 (2004)).

The present invention minimizes the internal reflection of LED light inside the LED package and minimizes the re-absorption of the LED light by the emitting layer (or the active layer) of the LED. The present invention furthermore combines the high light extraction efficiency LED chip with shaped (textured) phosphor layers to increase the total luminous efficacy of the device. As a result, this combined structure extracts more light out of the LED.

### SUMMARY OF THE INVENTION

The present invention describes a high efficient LED by minimizing the internal reflection inside of the molding with a sphere-shaped molded package, which is typically made from plastic. Assuming that the LED is a point light source and the size of the sphere molding is large, the direction of the all of the LED light beams to perpendicular to the surface of the sphere molding as shown in FIG. 1. Thus, all of the light can be extracted from the spherical LED package.

Also, the present invention describes an (Al, Ga, In)N and light emitting diode (LED) in which the multi directions of light can be extracted from the surfaces of the chip before entering the sphere shaped plastic optical element and subsequently extracted to air. In particular the (Al, Ga, In)N and transparent contact layers (ITO or ZnO) is combined with a sphere shaped lens in which most light entering lens lies within the critical angle and is therefore extracted. The present includes invention minimizing the internal reflection of LED light by mirrors without any intentional mirrors attached to LED chip in order to minimize the re-absorption of the LED light by the emitting layer (or the active layer) of the LED. In order to minimize the internal reflection of the LED light, transparent electrodes such as ITO or ZnO, or the surface roughening of AlInGaN by patterning or anisotropically etching, are used to extract more light from the LED. The present invention furthermore combines the high light extraction efficiency LED chip with shaped (textured) phosphor layers to increase the total luminous efficacy of the device. As a result, this combined structure extracts more light out of the LED.

A LED in accordance with the present invention comprises a LED chip, the LED chip emitting light at least a first emission wavelength; and a package, surrounding the LED chip, wherein the package has a substantially spherical shape.

Such an LED further optionally comprises the LED chip being located substantially at the center of the package, the package being made from a material that is transparent at the emission wavelength of the LED chip, a transparent conductor layer being placed on a p-type AlGaInN layer of the LED, the transparent conductor layer being made from a material selected from a group comprising Indium Tin Oxide (ITO) and Zinc Oxide (ZnO), the surface of the transparent conductor layer being roughened, a current spreading layer being deposited before the transparent conductor layer, the current spreading layer being made from a material selected from a group comprising SiO2, SiN, and other insulating materials, at least one surface of the LED chip being roughened, the LED chip emitting light from more than one side of the LED chip, the LED chip being fabricated on a sapphire substrate, wherein a back side of the sapphire substrate is roughened, a phosphor layer, coupled to the package, wherein the phosphor layer is located remotely from the LED chip, the LED chip being attached to a lead frame, the lead frame allowing for emission of light from opposite directions of the LED chip, the LED chip being made from a material selected from a group comprising a (Al, Ga, In)N material system, a (Al, Ga, In)As material system, a (Al, Ga, In)P material system, a (Al, Ga, In)AsPNSb material system, a ZnGeN2 material system, and a ZnSnGeN2 material system, and a mirror, optically coupled to the LED chip, wherein light emitted from one side of the LED chip is reflected to substantially align with light emitted from another side of the LED chip.

Another LED in accordance with the present invention comprises a group-III nitride based emission source, comprising an active layer and a textured surface layer, for emission of light in a first direction, and a second surface layer, opposite that of the textured surface layer, for emission of light in a second direction substantially opposite that of the first direction, and an encapsulation material, surrounding the group-III nitride based emission source, wherein the encapsulation material is substantially spherically shaped, a diameter of the encapsulation material being substantially larger than a width of the group-III nitride based emission source.

Such an LED further optionally comprises the second surface layer being textured, a phosphor layer, coupled to the encapsulation material, wherein light emitted from the LED excites the phosphor, a transparent conductive layer, coupled to the active layer, wherein the active layer emits light through the transparent conductive layer, the transparent conductive layer being made from a material selected from a group comprising Indium Tin Oxide and Zinc Oxide.

### BRIEF DESCRIPTION OF THE DRAWINGS

Referring now to the drawings in which like reference numbers represent corresponding parts throughout:

FIG. 1 illustrates a spherical LED in accordance with the present invention;

FIG. 2 illustrates a conventional LED package;

FIG. 3 illustrates a conventional LED package with a flip-chip LED;

FIG. 4 illustrates use of a conventional LED chip with the present invention;

FIGS. 5A and 5B illustrate an embodiment of the LED of the present invention;

FIG. 6 illustrates additional details of an embodiment of the present invention;

FIG. 7 illustrates details of another embodiment of the present invention;

FIGS. 8-15 illustrates embodiments of a spherical LED in accordance with the present invention; and

FIG. 16 illustrates the relative efficiency of various light sources, including the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

The present invention describes a high efficiency LED which minimizes the internal reflection inside of the molding via a sphere-shape molding. If the LED is considered a point light source and the size of the sphere molding is large compared to the LED chip, the direction of the LED light beams is approximately perpendicular to the surface of the spherical molding. Then, all of the light that is emitted from the LED is extracted from the sphere-shape molding into air. In conventional LEDs, the shape of molding is not spherical, as shown in FIGS. 2-4, so some of the LED light is reflected by the interface between the molding of the epoxy and the air due to a difference of the refractive index. This reflection reduces the efficiency or the output power of the LED due to a poor light extraction efficiency from the poor molding shape.

The present invention also describes an (Al, Ga, In)N light emitting diode (LED) in which the multiple directions of light can be extracted from the surfaces of the chip before entering the sphere shaped plastic optical element and subsequently extracted to air. In particular the (Al, Ga, In)N and transparent contact layers (ITO or ZnO) are combined with a spherically-shaped lens in which most light entering lens lies within the critical angle and is therefore extracted.

The present invention includes a high efficiency LED which minimizing the re-absorption of LED emission without any intentional mirrors attached to the LED chip. The conventional LEDs use a highly reflective mirror in order to increase the front emission by reflecting the LED light forward direction. See FIGS. 2-4. However, this reflected emission is typically partly re-absorbed by the emission layer or active layer of the LED, which reduces the efficiency or the output power of the LED. The present invention reduces reflection from the plastic encapsulating surface, reduces reflection from the ITO or ZnO surfaces, reduces reflection from the GaN by patterning or anisotropically etched surface (microcones), and minimizes light re-absorption by the emitting layer (active layer) without any intentional mirrors attached to the LED chip, which enables uniform light emission from the active layer to both sides of front and back sides. The present invention furthermore combines the high light extraction efficiency LED chip with shaped (textured) phosphor layers to increase the total luminous efficacy of the device. As a result, this combined structure extracts more light out of the LED.

### Technical Description

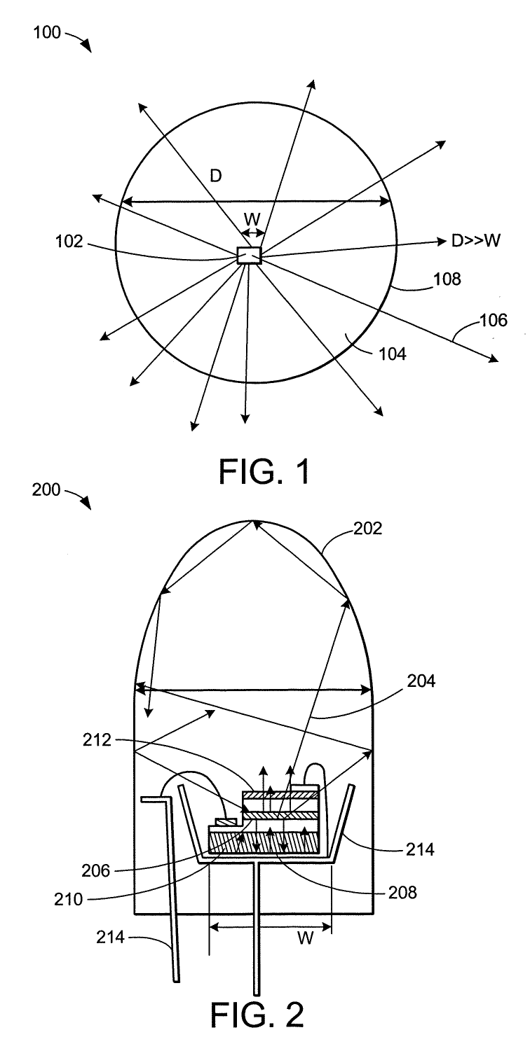

In FIGS. 1-16, the details of LED structure is not always shown. Only the emitting layer (usually AlInGaN MQW), p-type GaN, n-GaN, and the substrate are shown. In a typical LED structure, there are other layers such as a p-AlGaN electron blocking layer, InGaN/GaN super lattices, and others. Here, the most important parts are surface of the LED chip because the light extraction efficiency is determined mainly by the surface layer or condition of the epitaxial wafers, so, only these operational parts of the LED chip are shown in the figures.

FIG. 1 illustrates a spherical LED in accordance with the present invention.

LED 100, having chip 102 and molding 104, is shown. When the LED chip 102 is located at or near a center of a spherically-shaped molding 104, all of the LED light 106 generated by chip 102 is extracted from the molding 104 because the direction of the light 106 becomes substantially perpendicular to the surface 108 of the molding 104. In this case, the LED chip 102 should be like a spot light source. The molding 104 is typically a lens, made of plastic or epoxy, but can be made of glass or other transparent materials as desired. Further, the diameter of molding 104 is typically much larger than the width of chip 102, as shown in the drawing D>>W. The LED chip 102 can be point-like, or be of some size, so long as D>>W as shown in FIG. 1. Further, the LED light 106 can be of any color, e.g., blue, yellow, red, white, orange, etc., depending on the doping of the active layer of the LED chip 102.

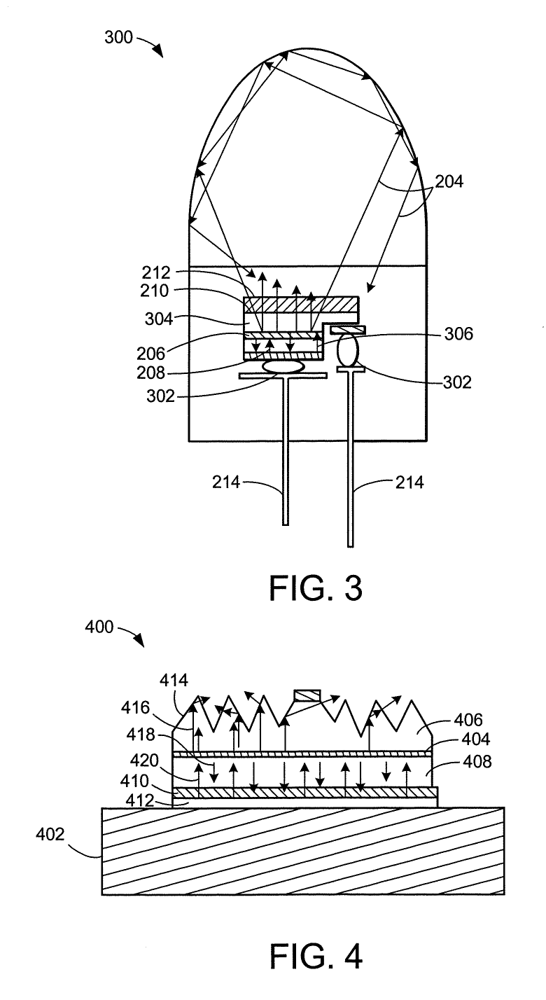

FIG. 2 illustrates a conventional LED package, and FIG. 3 illustrates a conventional LED package with a flip-chip LED.

In conventional LED packaging 200 shown in FIG. 2, the shape of the epoxy molding 202 is generally dome-shaped, not spherically-shaped. Thus, some of the LED light 204 generated by chip 206 is not extracted from the epoxy molding 202 of the dome, due to reflections inside of the epoxy molding 202. In such a dome-shaped molded package 200, the incident angle of the light 204 is often at an angle that is larger than a critical angle at the interface between the epoxy and the air, and thus is reflected back into the molding 202, and possibly reabsorbed by the active layer of the LED 206.

Also, in conventional LEDs 200, in order to increase the light 204 output power for the front side of the LED 206, the emitting light is reflected by a mirror 208 on the backside of the sapphire substrate 210. Other techniques for reflection of the light to the front side include a mirror coating on the lead frame when the bonding material is transparent at the emission wavelength. This reflected light is also re-absorbed by the emitting layer 206 (active layer) because the photon energy is almost same as the band-gap energy of the quantum well of AlInGaN multi-quantum well (MQW). Thus, the efficiency or output power of the LEDs 200 is decreased due to the re-absorption by the emitting layer.

In FIG. 2, the LED chip 212 is die-bonded on the lead frame 214 with a clear epoxy without any mirror on the back side of the sapphire substrate 210. In this case, the coating 208 material on the lead frame 214 becomes a mirror. If there is a mirror on the back side of the substrate, the LED chip is typically die-bonded by Ag paste.

FIG. 3 illustrates a typical flip-chip packaging schema.

LED package 300 is shown, similar to LED package 200. In LED package 300, however, chip 212 is flip-chip mounted to lead frames 214 using electrically conductive bumps 302, which are typically indium but can be any electrically conductive material that is compatible with LED 212. Now, light 304 reflects from mirrored surface 208 and becomes light 306, which can then exit package 300 if the angle of the reflected light 300 is less than the critical angle at the interface between package 300 and the air or other material that is in contact with the outside of package 300.

FIG. 4 illustrates use of a conventional LED chip with the present invention.

In FIG. 4 the epoxy molding 104 in accordance with the present invention is not shown. The spherically-shaped molding 104 is typically attached as shown in FIG. 1 using a conventional LED chip 102 to increase the light extraction efficiency. The diameter of the sphere molding should be much larger than size of the LED chip 102 to ensure that the light emitted by the LED chip will strike the interface between the epoxy molding and the air at a perpendicular or normal angle, which allows the light to leave the plastic and enter the air. Any light that strikes the interface between lens and air at less than the critical angle will escape into the air, but to make that angle uniform across the entire LED device, a sphere is chosen. However, any shape where the surface profile between lens and air is less than the critical angle will allow the light to escape, and is in accordance with the present invention.

LED chip 400 with substrate 402, active layer 404, and surface layer 406 is shown. Additional layers 408, 410, and 412 are also shown, to show the entire structure of chip 400. Surface layer 406 of the present invention is not a planar surface. Surface layer 406 has a top surface 414 that is textured, patterned, or otherwise roughened to allow for light 416 that is incident on surface 414 to escape into the surrounding medium. The surrounding medium in most cases is molding 100, but could be other materials without departing from the scope of the present invention. Since the critical angle of molding 100 allows for any perpendicular or substantially perpendicular light to escape from package 100, the direction of light 416 is not so critical as it is in the packages 200 and 300 shown in FIGS. 2 and 3 respectively.

Further, light 418 can be reflected from substrate 402, or layers 410-412, such that light 418 becomes light 420, which also has an opportunity to escape from chip 400.

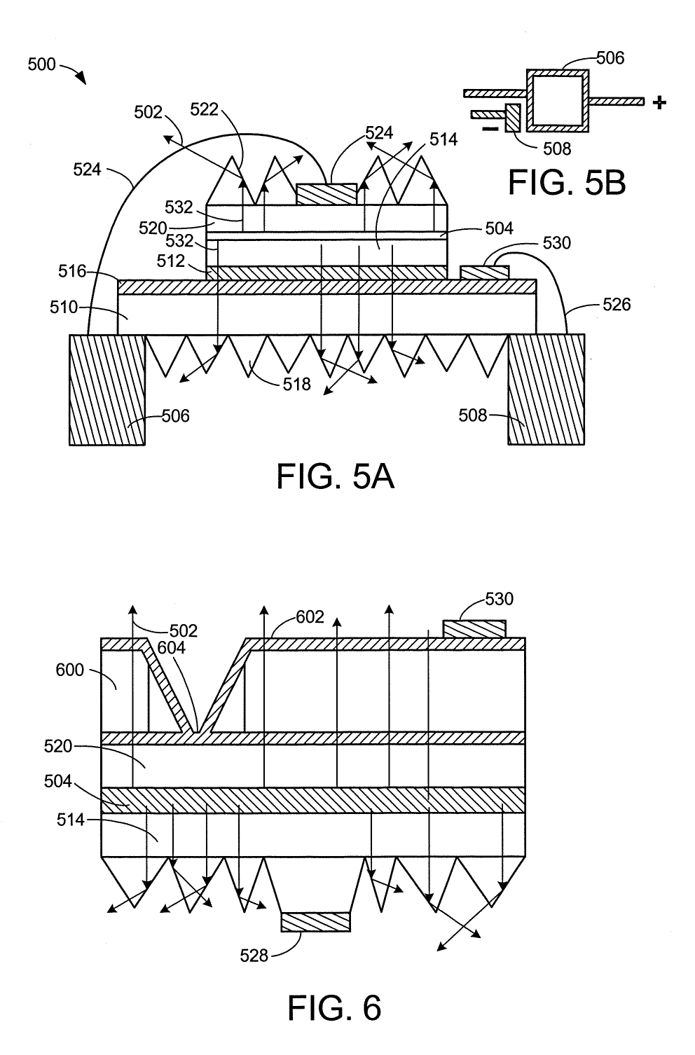

FIGS. 5A and 5B illustrate an embodiment of the LED of the present invention.

LED 500 with emitted light 502 and active layer 504 are shown. Lead frame 506 and electrode 508 are shown as supporting glass plate 510.

In FIG. 5, the LED structure 500 is shown as being grown on a sapphire substrate. Then, Indium Tin Oxide (ITO) layer 512 is deposited on p-type GaN layer 514. Then, an ITO layer 516 is coated onto glass plate 510, and is attached to the deposited ITO layer 512 using epoxy as a glue. The other side 518 of glass plate 510 is roughened, patterned, or otherwise given a non-planar profile by a sand blast or other roughening technique, such as etching. Then, the sapphire substrate is removed using the laser de-bonding technique. Then, the Nitrogen-face (N face) GaN 520 is etched with wet etching such as KOH or HCL. Then, a cone-shaped surface 522 is formed on Nitrogen-face GaN 520. Then, LED chip 500 is put on a lead frame 506 which works for removing any heat that is generated by the LED chip 500. The wire bonding 524 and 526 is done between bonding pads of the LED chip 528 and 530 and a lead frame 506 and electrode 508 to allow an electric current to flow through the lead frame 506. There are no intentional mirrors at the front and back sides of LED chip 500. The lead frame 506 is designed to extract the light from the back side of the LED chip effectively as shown in the figure, because lead frame 506 acts as a support around the edges of LED chip 500, rather than supporting the entire underside of chip 500. As such, the LED light 532 is effectively extracted to both sides as emitted light 502. The ohmic contact below the bonding pad of n-GaN is not shown for simplicity. Then, the LED chip 500 is molded with a sphere shape molding 100 of plastic, epoxy, or glass, which acts as a lens to assist the emitted light 532 to escape from the LED and enter the air.

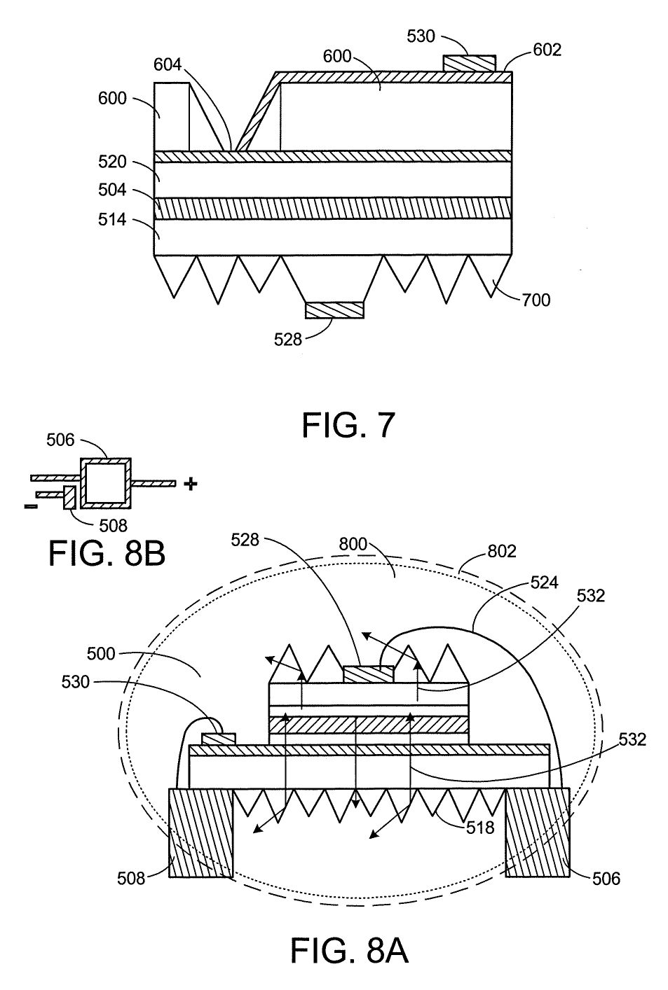

FIG. 6 illustrates additional details of an embodiment of the present invention, and FIG. 7 illustrates details of another embodiment of the present invention.

In FIGS. 6 and 7, instead of the glass layer 510 as shown in FIG. 5, a thick epoxy 600 is used. To make the electric contact, the epoxy 600 is partially removed, and ITO or a narrow stripe Au layer 602 is deposited on the epoxy 600 and the hole 604. The operation of the LED is similar to the LED described with respect to FIG. 5, except layer 514 is now roughened on the opposite side of active layer 504 to allow for additional light to be emitted from the reverse side of active layer 502.

In FIGS. 5-7, if a GaN substrate is used instead of a sapphire substrate, the laser de-bonding step is not required, and, as such, the glass and thick epoxy sub-mount are also not required. After the LED structure growth on GaN substrate, ITO is deposited on p-type GaN and the backside of GaN substrate (typically Nitrogen-face GaN) is etched with a wet etching such as KOH and HCL. Then a cone-shaped surface is formed on the Nitrogen face GaN. The remainder of the fabrication and operational steps are similar to the LED described with respect to FIG. 5.

Also, when the surface of ITO layers, e.g., layers 512, 516, etc., are roughened, the light extraction through the ITO layers 512, 516 is increased. Even without the ITO layer 512 that is deposited on the p-type GaN layer 514, the roughening of the surface of p-type GaN 514 as surface 700 is effective to increase the light extraction through the p-type GaN 514. To create an ohmic contact for n-type GaN layer 520, ITO or ZnO are typically used after the surface roughening of Nitrogen-face GaN layer 520. Since ITO and ZnO have a similar refractive index as GaN, the light reflection at the interface between ITO (ZnO) and GaN is minimized.

FIGS. 8-15 illustrates embodiments of a spherical LED in accordance with the present invention.

In FIG. 8A, the LED chip of FIG. 5 is molded with epoxy or glass 800 as a sphere shape. In this case, the light 532 is extracted to air through the sphere molding 800 effectively, because the LED chip 500 is a small spot light source compared to the diameter of the spherical lens 800. In addition, a phosphor layer 802 is placed or deposited near the outside surface of the lens molding 800. In this case, the conversion efficiency of the blue light to white light is increased due to a small re-absorption of the LED light 532 due to a small back scattering of the LED light 532 by the phosphor layer 802. Also, when the surface of the molding 800 or the phosphor layer 802 is roughened, the light extraction is increased from the molding 800 and/or the phosphor 802 to the air. FIG. 8B illustrates that chip 500 is mounted on frame 506 such that light 532 is also emitted from led 500 via surface 518 on the back side of chip 500.

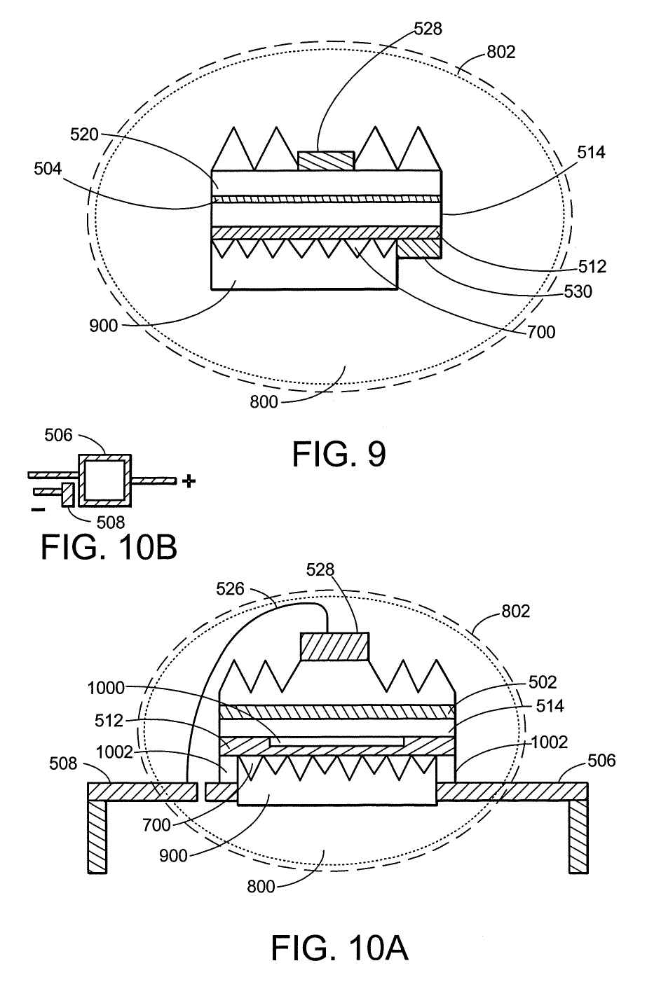

In FIG. 9, in the LED chip of FIGS. 6-7, the ITO or ZnO is roughened as surface 700 to improve the light extraction through the ITO or ZnO. Then, the epoxy 900 is sub-mounted.

In FIG. 10, before the ITO or ZnO deposition, a current spreading layer (SiO2, SiN, transparent insulating material) 1000 is deposited to allow a uniform current to flow through the p-type GaN layer 512, and contact 1002 is provided to contact frame 506.

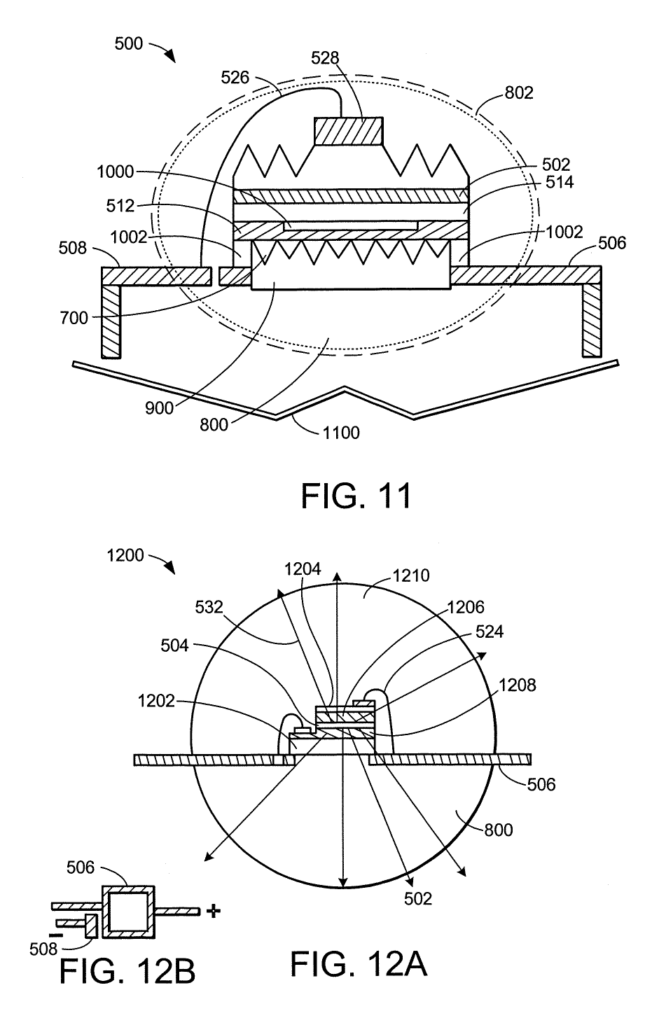

In FIG. 11, a mirror 1100 is put outside of the sphere molding 800 in order to direct more light to a specific side of the LED package 500. The shape of the mirror 1100 is typically designed such that any reflected light is directed away from the LED chip 500 to avoid or minimize reabsorption of light by the active layer 502 of the LED chip 500.

In FIG. 12, the LED structure 1200 is shown as grown on a flat sapphire substrate or a patterned sapphire substrate (PSS) 1202 to improve the light extraction efficiency through the interface between the GaN and the sapphire substrate 1202. Also, the backside of the sapphire substrate 1202 is roughened to increase the light extraction from the sapphire substrate 1202 to the air or epoxy or glass. Typically, the preferred shape of the roughened surface has a cone-shaped surface, but other surfaces may be used in accordance with the present invention. Then ITO or ZnO layer 1204 is deposited on p-type GaN 1206. Then, bonding pads on ITO or ZnO and an ohmic contact/bonding pad on n-type GaN 1208 are formed after the n-type GaN 1208 is selectively etched. Then, the LED chip 1200 is molded with a lens 1210 of approximately spherical shape.

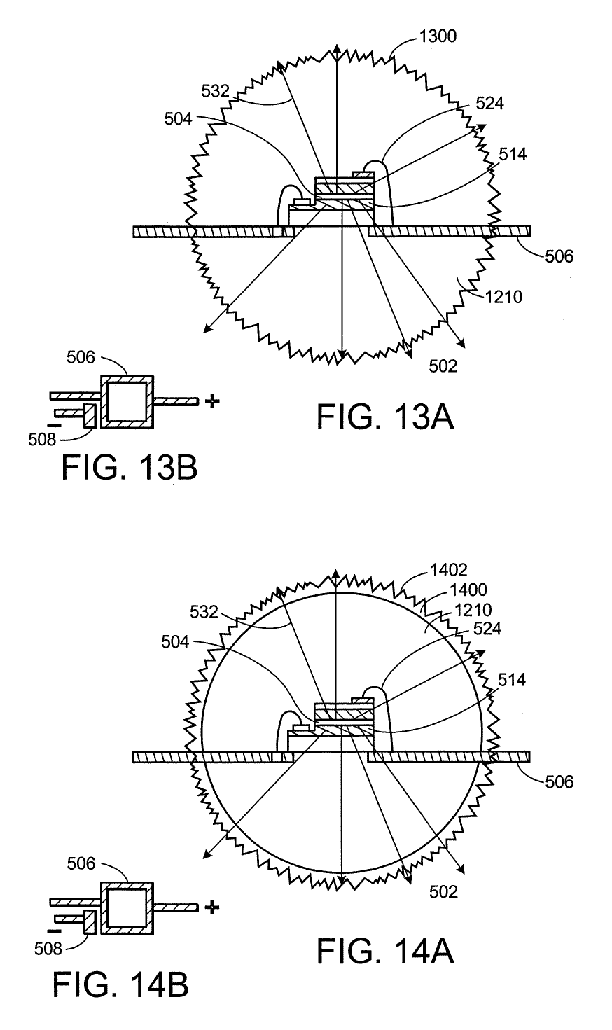

In FIG. 13, the surface 1300 of the epoxy molding 1210 is roughened to increase the light extraction through the epoxy molding 1210. Similar roughening techniques can be applied to glass or other transparent materials used for molding 1210 without departing from the scope of the present invention.

In FIG. 14, a phosphor layer 1400 is deposited or placed near the top surface of the lens epoxy molding 1210. This allows for the phosphor layer 1400 to be placed a relatively far distance from the LED chip 500, which allows for an increase in the conversion efficiency of the blue light to white light due to a small re-absorption of the LED light 532 via a small back scattering by the phosphor 1400 to the LED chip 500. The surface 1402 of the phosphor layer 1400 can be roughened to improve the light extraction through the phosphor layer 1400.

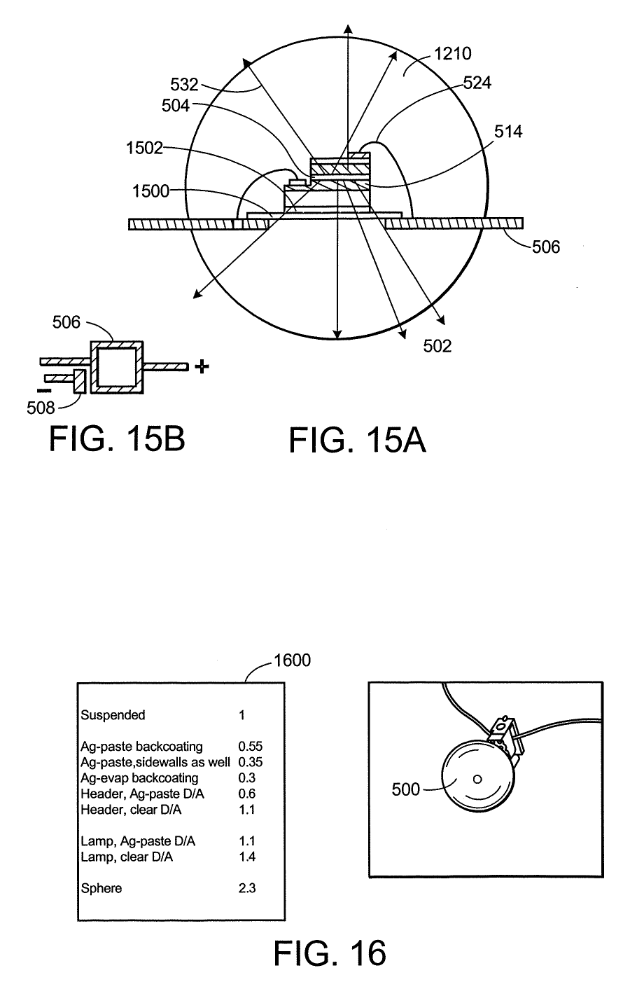

In FIG. 15, a lead frame 506 is used, and the LED chip is put on a transparent plate 1500 such as glass, quartz, sapphire, diamond or other transparent materials, using a transparent epoxy 1502 as a die-bonding material. The transparent glass plate 1500 is used to extract the LED light to the epoxy molding 1210 more effectively.

FIG. 16 illustrates the relative efficiency of various light sources, including the present invention.

In FIG. 16, table 1600 compares the spherical LED of the present invention to other LED packages and LED types, and it can be seen that the highest output power and efficiency is achieved by the spherical LED 500 of the present invention compared to other LED types with a different molding shape. Although LED 500 is shown in FIG. 16, similar packaging would be shown for any of the spherical LEDs of the present invention described in FIGS. 5-15.

### Advantages and Improvements

The present invention describes a high efficient LED by minimizing the internal reflection inside of the molding with a sphere-shape molding. By packaging the epoxy and LED such that LED approximates a point light source, the direction of all of the LED light beams end up as being perpendicular to the surface of the spherical lens molding.

Also, by combining the LED structure without any intentional mirrors attached to LED chip (the mirror coated on lead frame is also included as the intentional mirrors), the re-absorption of LED light is minimized and the light extraction efficiency is increased dramatically. Thus, the light output power of the LEDs is also increased dramatically.

The combination of a transparent oxide electrode with a surface roughened nitride LED and shaped lens results in further increases in light extraction.

### REFERENCES

The following references are incorporated by reference herein:
1. Appl. Phys. Lett. 56, 737-39 (1990).
2. Appl. Phys. Lett. 64, 2839-41 (1994).
3. Appl. Phys. Lett. 81, 3152-54 (2002).
4. Jpn. J. Appl. Phys. 43, L1275-77 (2004).
5. Jpn. J. Appl. Physics, 45, No. 41, L1084-L1086 (2006).
6. Fujii T, Gao Y, Sharma R, Hu E L, DenBaars S P, Nakamura S. Increase in the extraction efficiency of GaN-based light-emitting diodes via surface roughening. Applied Physics Letters, vol. 84, no. 6, 9 Feb. 2004, pp. 855-7. Publisher: AIP, USA

### CONCLUSION

The present invention describes light emitting diodes. A LED in accordance with the present invention comprises a LED chip, the LED chip emitting light at least a first emission wavelength; and a package, surrounding the LED chip, wherein the package has a substantially spherical shape.

Such an LED further optionally comprises the LED chip being located substantially at the center of the package, the package being made from a material that is transparent at the emission wavelength of the LED chip, a transparent conductor layer being placed on a p-type AlGaInN layer of the LED, the transparent conductor layer being made from a material selected from a group comprising Indium Tin Oxide (ITO) and Zinc Oxide (ZnO), the surface of the transparent conductor layer being roughened, a current spreading layer being deposited before the transparent conductor layer, the current spreading layer being made from a material selected from a group comprising SiO2, SiN, and other insulating materials, at least one surface of the LED chip being roughened, the LED chip emitting light from more than one side of the LED chip, the LED chip being fabricated on a sapphire substrate, wherein a back side of the sapphire substrate is roughened, a phosphor layer, coupled to the package, wherein the phosphor layer is located remotely from the LED chip, the LED chip being attached to a lead frame, the lead frame allowing for emission of light from opposite directions of the LED chip, the LED chip being made from a material selected from a group comprising a (Al, Ga, In)N material system, a (Al, Ga, In)As material system, a (Al, Ga, In)P material system, a (Al, Ga, In)AsPNSb material system, a ZnGeN2 material system, and a ZnSnGeN2 material system, and a mirror, optically coupled to the LED chip, wherein light emitted from one side of the LED chip is reflected to substantially align with light emitted from another side of the LED chip.

Another LED in accordance with the present invention comprises a group-III nitride based emission source, comprising an active layer and a textured surface layer, for emission of light in a first direction, and a second surface layer, opposite that of the textured surface layer, for emission of light in a second direction substantially opposite that of the first direction, and an encapsulation material, surrounding the group-III nitride based emission source, wherein the encapsulation material is substantially spherically shaped, a diameter of the encapsulation material being substantially larger than a width of the group-III nitride based emission source.

Such an LED further optionally comprises the second surface layer being textured, a phosphor layer, coupled to the encapsulation material, wherein light emitted from the LED excites the phosphor, a transparent conductive layer, coupled to the active layer, wherein the active layer emits light through the transparent conductive layer, the transparent conductive layer being made from a material selected from a group comprising Indium Tin Oxide and Zinc Oxide.

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto and the full range and scope of equivalents to the claims.

What is claimed is:

1. A Light Emitting Diode (LED), comprising:
a LED chip, the LED chip emitting light at least a first emission wavelength; and
a package, surrounding the LED chip, wherein the package has a substantially spherical shape.

2. The LED of claim 1, wherein the LED chip is located substantially at the center of the package.

3. The LED of claim 1, wherein the package is made from a material that is transparent at the emission wavelength of the LED chip.

4. The LED of claim 1, wherein a transparent conductor layer is placed on a p-type AlGaInN layer of the LED.

5. The LED of claim 4, wherein the transparent conductor layer is made from a material selected from a group comprising Indium Tin Oxide (ITO) and Zinc Oxide (ZnO).

6. The LED of claim 4, wherein the surface of the transparent conductor layer is roughened.

7. The LED of claim 4, wherein a current spreading layer is deposited before the transparent conductor layer.

8. The LED of claim 7, wherein the current spreading layer is made from a material selected from a group comprising SiO2, SiN, and other insulating materials.

9. The LED of claim 1, wherein at least one surface of the LED chip is roughened.

10. The LED of claim 1, wherein the LED chip emits light from more than one side of the LED chip.

11. The LED of claim 1, wherein the LED chip is fabricated on a sapphire substrate, wherein a back side of the sapphire substrate is roughened.

12. The LED of claim 1, further comprising a phosphor layer, coupled to the package, wherein the phosphor layer is located remotely from the LED chip.

13. The LED of claim 1, wherein the LED chip is attached to a lead frame, the lead frame allowing for emission of light from opposite directions of the LED chip.

14. The LED of claim 1, wherein the LED chip is made from a material selected from a group comprising a (Al, Ga, In)N material system, a (Al, Ga, In)As material system, a (Al, Ga, In)P material system, a (Al, Ga, In)AsPNSb material system, a ZnGeN2 material system, and a ZnSnGeN2 material system.

15. The LED of claim 10, further comprising a mirror, optically coupled to the LED chip, wherein light emitted from one side of the LED chip is reflected to substantially align with light emitted from another side of the LED chip.

16. A Light Emitting Diode (LED), comprising:
a group-III nitride based emission source, comprising
an active layer and a textured surface layer, for emission of light in a first direction; and
a second surface layer, opposite that of the textured surface layer, for emission of light in a second direction substantially opposite that of the first direction; and
an encapsulation material, surrounding the group-III nitride based emission source, wherein the encapsulation material is substantially spherically shaped, a diameter of the encapsulation material being substantially larger than a width of the group-III nitride based emission source.

17. The LED of claim 16, wherein the second surface layer is textured.

18. The LED of claim 17, further comprising a phosphor layer, coupled to the encapsulation material, wherein light emitted from the LED excites the phosphor.

19. The LED of claim 16, further comprising a transparent conductive layer, coupled to the active layer, wherein the active layer emits light through the transparent conductive layer.

20. The LED of claim 19, wherein the transparent conductive layer is made from a material selected from a group comprising Indium Tin Oxide and Zinc Oxide.
